(19) United States
(12) Patent Application Publication
(10) Pub. No.: US 2007/0030064 A1
(43) Pub. Date: Feb. 8, 2007

(54) Integrated laterally diffused metal oxide semiconductor power detector

(76) Inventor: Yinglei Yu, Tempe, AZ (US)

Correspondence Address: MOTOROLA, INC., 1303 EAST ALGONQUIN ROAD, IL01/3RD, SCHAUMBURG, IL, 60196, US

(21) Appl. No.: 11/196,465

(22) Filed: Aug. 3, 2005

(51) Int. Cl. H03G 3/20

(52) U.S. Cl. 330/140

(57) ABSTRACT

An integrated LDMOS power detection circuit for radio frequency power detection is disclosed wherein the circuit includes a first LDMOS transistor, a first resistor coupled between the first LDMOS transistor and a power source, a second LDMOS transistor coupled to the first LDMOS transistor, a input resistive voltage divider and at least one PMOS transistors coupled between the second LDMOS transistor and a second resistor, wherein the PMOS transistor functions as a current mirror for the circuit and the first and the second resistors function as a indirect resistor divider for the circuit.

### FIELD OF THE INVENTION

The present invention relates generally to laterally diffused metal oxide semiconductors (LDMOS) and, in particular, to an integrated LDMOS circuit that performs adaptive radio frequency power detection and could be fully integrated with an integrated LDMOS radio frequency power amplifier.

### BACKGROUND

Radio frequency (RF) power amplifiers (PA) are used in a wide variety of communications and other electronic applications. In high power cellular base station system, laterally diffused metal oxide semiconductors (LDMOS) power amplifier attracts special attention due to its low cost, high efficiency, high linearity and excellent reliability. However, a single stage LDMOS RF PA by itself can seldom meet the gain requirement or the high power requirement (hundreds to thousands of Watts) of the whole base station system. Typically, several PA stages are cascaded to meet the system gain requirement and the power requirement is generally satisfied by power-combining several PA stages of lower power, which could be realized by an integrated LDMOS PA or a discrete single stage LDMOS PA.

Power amplifiers that are used in communication systems, as discussed above, may require power detectors associated with the power amplifiers to monitor performance and to determine whether every power amplifier in a cascade or in a power-combining configuration is functioning normally or abnormally. These power detectors could also be utilized for other purposes, such as power control, linearization and automatic gain control (AGC). Currently, power detectors are typically formed by off-chip couplers and circuits external to the power amplifier. These off-chip external detectors generally occupy large board areas, increase cost and require calibration in application.

In addition to needing calibration, external off-chip detectors are susceptible to other aspects of board design and performance. In particular, the output of the power detectors can be dependent on the temperature variances of the amplifier and the environment in which the power amplifier and power detector operate and during manufacture. In addition, power detection can be dependent on the process variations of the amplifier and the environment in which the devices operate and during manufacture. For example, the coupling coefficient of an external coupler may vary significantly over above variances. These uncertainties definitely degrade the accuracy of power detection and limit the application of power detectors.

In addition, LDMOS RF power amplifier may have very low output impedances, making it difficult to design power detectors that do not degrade the transistor's performance. In order to facilitate the use of such transistor in an RF power amplifier, power detectors are typically designed as separate elements from the RF power transistor. The performance of the power detector is therefore distanced from the performance of the LDMOS power amplifier. Integration of components, such as a power amplifier and power detector for use with LDMOS RF transistors, has not been successful because the performance effects on the output of the RF power amplifier.

While integration of RF power amplifier and power detector onto a single chip would be desirable to reduce costs and space, there are a number of challenges that need to be overcome. In order for the power detector to operate effectively and efficiently, the power amplifier and the power detector should be correctly coupled so that the output power of the RF power amplifier is provided to the power detector with causing minimum affect on the output of the amplifier. In addition, the RF power should be coupled linearly to the power detector and should be converting to repeatable DC voltages for correlation purpose.

The prior art, as seen in EP 1050956A1, discloses a detector circuit for detecting waves without distortion. The detector circuit disclosed has a configuration similar to a circuit mirror in which the FETs are connected together through a resistor between their gates and an input AM-modulated wave signal is couple to one end of the resistor. The prior art as it is cannot be used for RF power detection purpose. What is needed, however, is an on-chip resistive voltage divider to couple to the input signal that is highly repeatable and with high impedance to the RF amplifier without loading the RF power amplifier. The bypass cap at the drain of the detector FET reduces or eliminates the RF amplification. Moreover, in wave detection application, several FETs in the prior art are biased in triode region for linearity reasons. Therefore, the output of the prior art tracks input voltage amplitude in best case. In power detection application, however, this approach is not suitable since it significantly degrades sensitivity and dynamic range. Besides, the output of a RF power detector should track the input power instead of voltage amplitude. Oppositely, all FETs should be biased in saturation region in order to utilize the square-law relationship of LDMOS between drain current and gate voltage for power detection.

As is known, power detectors may advantageously use current mirrors. For a PMOS current mirror, as disclosed in the prior art, it is desired to extend the output voltage range with a higher resolution, while providing detection sensitivity and wide bandwidth. Moreover, it would be beneficial that the load resistor could be adjusted for conversion gain.

Bipolar circuits for LDMOS and PMOS transistors are also disclosed in Japanese Patents JP58220506 and JP61164304. These bipolar transistors, however, cannot be integrated with an LDMOS power amplifier due to the use of the bipolar transistors. In addition, these Japanese references, while having an on- chip resistor divider that couples to the input signal that is highly repeatable with different impedances, it is beneficial to have a circuit that does not degrade the performance of the RF amplifier. Moreover, these references include a bypass cap at the drain of the detector that effectively kills RF amplification.

In view of the foregoing, there is a desire to overcome the obstacles of the prior art in integrating a power detector with an integrated LDMOS power amplifier circuit. The prior art presents issues including how to couple the RF power to the power detector, converting the RF power linearly to a DC voltage, having the power detector independent of the numerous variances within the integrated circuit, and all while not affecting the overall performance of the RF power amplifier.

### BRIEF DESCRIPTION OF THE FIGURES

The accompanying figures, where like reference numerals refer to identical or functionally similar elements throughout the separate views and which together with the detailed description below are incorporated in and form part of the specification, serve to further illustrate various embodiments and to explain various principles and advantages all in accordance with the present invention.

FIG. 1 is an example of a diagram of an integrated RF power detection circuit in accordance with some embodiments of the invention.

FIG. 2 is another example of a diagram of an integrated RF power detection circuit in accordance with embodiments of the invention.

FIG. 3 illustrates power detector output in accordance with some embodiments of the invention.

Skilled artisans will appreciate that elements in the figures are illustrated for simplicity and clarity and have not necessarily been drawn to scale. For example, the dimensions of some of the elements in the figures may be exaggerated relative to other elements to help to improve understanding of embodiments of the present invention.

### DETAILED DESCRIPTION

Before describing in detail embodiments that are in accordance with the present invention, it should be observed that the embodiments reside primarily in combinations of method steps and apparatus components related to an integrated LDMOS transistor RF power amplifier and power detector circuit. Accordingly, the apparatus components and method steps have been represented where appropriate by conventional symbols in the drawings, showing only those specific details that are pertinent to understanding the embodiments of the present invention so as not to obscure the disclosure with details that will be readily apparent to those of ordinary skill in the art having the benefit of the description herein.

In this document, relational terms such as first and second, top and bottom, and the like may be used solely to distinguish one entity or action from another entity or action without necessarily requiring or implying any actual such relationship or order between such entities or actions. The terms “comprises,” “comprising,” or any other variation thereof, are intended to cover a non-exclusive inclusion, such that a process, method, article, or apparatus that comprises a list of elements does not include only those elements but may include other elements not expressly listed or inherent to such process, method, article, or apparatus. An element proceeded by “comprises . . . a” does not, without more constraints, preclude the existence of additional identical elements in the process, method, article, or apparatus that comprises the element.

It will be appreciated that embodiments of the invention described herein may be comprised of one or more conventional processors and unique stored program instructions that control the one or more processors to implement, in conjunction with certain non-processor circuits, some, most, or all of the functions of an integrated LDMOS transistor RF power amplifier and power detector circuit as described herein. The non-processor circuits may include, but are not limited to, a radio receiver, a radio transmitter, signal drivers, clock circuits, power source circuits, and user input devices. As such, these functions may be interpreted as steps of a method to perform an integrated LDMOS transistor RF power amplifier and power detector circuit. Alternatively, some or all functions could be implemented by a state machine that has no stored program instructions, or in one or more application specific integrated circuits (ASICs), in which each function or some combinations of certain of the functions are implemented as custom logic. Of course, a combination of the two approaches could be used. Thus, methods and means for these functions have been described herein. Further, it is expected that one of ordinary skill, notwithstanding possibly significant effort and many design choices motivated by, for example, available time, current technology, and economic considerations, when guided by the concepts and principles disclosed herein will be readily capable of generating such software instructions and programs and ICs with minimal experimentation.

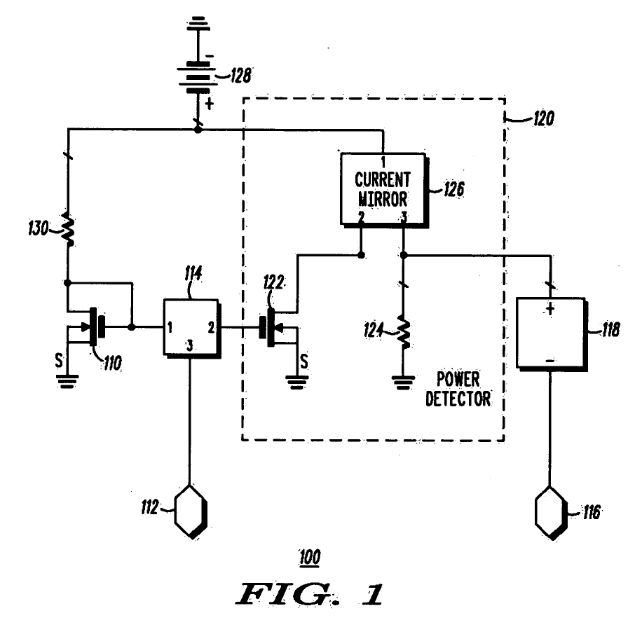

Referring to FIG. 1, there is illustrated a block diagram of an integrated radio frequency (RF) power detector network, or circuit, 100 according to the principles of the present invention. Typically, but not necessarily, network 100 is connected to the final stage (not shown) of an integrated power amplifier system used, for instance, in a communications device, wherein the power amplifier system may comprise a plurality of power amplifier networks in cascaded or power combining configuration. This integrated power amplifier system signaling preferably anticipates both narrow band signals, such as, for example, a Frequency Division Multiple Access (FDMA) formant or a Code Division Multiple Access (CDMA) formant. In addition to comprising multiple formats, the anticipated signaling environment of RF power amplifier network is further characterized by input signals that exhibit a wide and dynamic range of input power levels (or amplitudes.)

RF power detector network 100 includes an RF power detector having a plurality of operating performance characteristics responsive to a quiescent operating point. The RF power detector comprises a first transistor 110. Preferably both the transistors 110 and 122 (discussed in detail below) are identical lateral diffused metal-oxide semiconductor (LDMOS) field effect transistors (FET) of small gate periphery having their sources coupled to a fixed voltage, preferable a ground potential. These two LDMOS FETs should be close to each other on the same chip. The RF power detector further comprises input port 112 for receiving the input signal, and preferably an input coupling circuit 114 coupled between input 112 and the gates transistors 110 and 122 for effectively delivering the RF power of interested point to transistor 122. The input 112 of this network is generally connected to the drain of the final stage of an integrated RF power amplifier or any point of interest within the integrated power amplifier. The RF power detector still further comprises an output load 116, a current mirror 126 and, preferably, an output filtering circuit 118 coupled between output 116 and current mirror 126 for harmonic filtering purpose and time constant adjustment. Power source for the circuit is provided by a DC voltage 128

RF power detection network 100 further includes an adaptive detector circuit 120 integrally configured with the bias portion of the network according to the principles of the present invention. The power detector circuit comprises circuit 120 that is preferably coupled to the gate of the transistor 110 and the output 116 through output filtering circuit 118.

Circuit 120 comprises a number of different elements including a transistor 122, resistor 124, and current mirror 126. The second transistor 122 is also a LDMOS FET and it is identical to its bias transistor 110. Resistor 124 is configured to be a resistive load of current mirror 126. Current mirror 126 forces the DC current flowing through resistor 124 is proportional to the DC drain current of transistor 122. The current mirror 126 can be configured as any type of current mirror known or that will be developed.

Referring still to FIG. 1, the gate of the transistor 122 is both DC coupled to the gate of first transistor 110 as well as RF coupled to RF input port 112 and input coupling circuit 114. The drain of transistor 122 is coupled to the resistive load 124 through the current mirror 126. As seen, the current mirror is coupled between the transistor 122 and the power source 128. Between the current mirror 126 and the resistive load 124, the output port 116 and output filtering circuit 118 are connected for network 100. In addition, the output of the power detector circuit 120 is measured at output port 116.

In addition to the power detector circuit 120, RF power detection network 100 also includes a second resistor 130 that is coupled between the power source 128 and the transistor 110. The second resistor 130 operates as a clamping resistor for bias transistor 110 and serves to bias the power detector circuit 120 through current-mirroring mechanism.

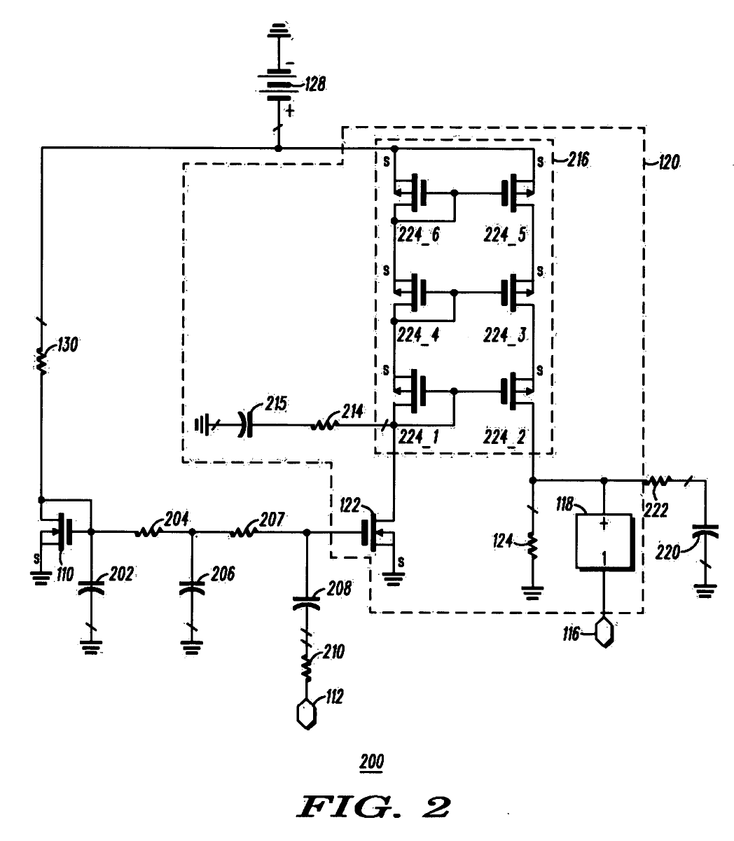

Referring now to FIG. 2, there is illustrated an alternate embodiment of the RF power detection network 200 according to the present invention. Like components shown in other figures are given identical numbers as in all figures. As seen in FIG. 2, the RF power detection network 200 includes a LDMOS FET transistor 110, input port 112, and an input coupling circuit (not shown). Input components can be configured with third capacitor 208 and resistor 210. These components are configured as described above for FIG. 1. Power detection network 200 also includes the output port 116 and output load 118 similar to that described for network 100. Between the gate of the first transistor 110 and the power detector circuit 120, power detection network 200 includes a capacitor 202 and resistor 204 and second capacitor 206 and resistor 207. These capacitor/resistor combinations provide RF isolation and DC bias path between bias transistor 110 and adaptive detection circuit 120.

Adaptive detection circuit 120 shown in FIG. 2 includes the LDMOS FET transistor 122. The drain of transistor 122 is coupled to a capacitor 214 through resistor 215 such that capacitor 214 operates as a shunt cap for the power detector 120. Similar to other embodiments of the present invention, a current mirror 216 forces the DC current flowing through resistive load 124 proportional to the drain current of transistor 122. A capacitor 220 and resistor 222 are coupled to the current mirror 216 and the output 116 to operate as yet another shunt cap for the network 200.

As with the network 100, power detection network 200 includes resistors 124 and 130. Resistor 124 operates as the resistive load, and resistor 130 operates as a biasing resistor for the adaptive power detector 120. Through current mirror 216, these two resistors form an indirect voltage divider. The ratio of these two resistors creates a reference output voltage corresponding to zero RF power input. In semiconductor processing, parameters which affect the values of resistors, such as the sheet resistance of the material, the thickness of the layer, width of the line and local temperature increases or decreases uniformly on the same chip. Therefore, by integrating resistors 124 and 130 on the same chip and on the same layer, taking special layout consideration and place them close to each other, the zero-input reference voltage is independent of the resistor values of either resistor 124 or 130, environment temperature and process variation. Thus, the zeroing process associated with pre-arts become unnecessary in present invention.

Current mirror 216 includes at least one P-channel metal oxide semiconductor (PMOS) transistor 224. As seen in the figure, in one embodiment, the current mirror 216 is made up of six different PMOS transistors 224. A first set of three of the PMOS transistors are connected in series such that the drain of each transistor 224 is coupled to the source of the next transistor 224. The source of the first transistor 224 is coupled to the power source 128. In addition, the drain of each transistor 224 is coupled to its gate. Moreover, the second set of three PMOS transistors are connected in series such that the drain of each transistor 224 is coupled to the source of the next transistor 224. Similar to the first set of transistors 224 in series the first PMOS transistor of the second set of transistors in series is coupled to the power source 128. To connect the first and second sets of transistors in parallel the gate of first transistor in the first series is coupled to the gate of the first transistor in the second series and the gate of the second transistor in the first series is coupled to the gate of the second transistor in the second series, and so forth. This cascaded current mirror arrangement is mainly for high voltage operation. For higher or lower voltage operation, cascaded current mirror of more or fewer than three pairs could be utilized.

The RF power detection networks described herein preferably function as follows. Input port 112 and input coupling circuit 114 provide a sample of the RF power to be detected to the power detection network 100, 200. Input port 112 is generally connected to the drain of the final stage of an integrated RF power amplifier or any point of interest within the integrated power amplifier. Since resistors 210 and 207 form a voltage divider, the ratio of the sampled signal to the RF signal to be detected, which is described as coupling coefficient, equals to the ratio of these two resistors. Due to the properties of semiconductor process mentioned above, by integrating resistors 210 and 207 on the same chip and on the same layer, taking special layout consideration and place them close to each other, the input coupling coefficient is independent of the resistor values of either resistor 210 or 207, environment temperature and process variations and could be used as the system reference. Thus, the calibration process associated with pre- arts could be avoided in present invention.

Low pass filter circuit consisting of resistors 204, 207 and bypass capacitors 202, 206 isolates the sampled RF signal from bias transistor 110 so that a stable bias point is provided for the adaptive power detection circuit 120. Moreover, the high impedance provided by the input coupling circuit 114 guarantees that the power detection circuit described in present invention does not degrade the performance of the integrated power amplifier.

As will be appreciated by one skilled in the art, the power detector 120 detects the functionality of the power amplifier and may monitor the output power level of the amplifier. Moreover, the output signal from the power detector may be used for automatic gain control (AGC) of the power amplifier. In order to achieve the desired detection, the resistors 124, 130 and current mirror 216 of the power detector operate as an indirect resistor divider to the power detector. Accordingly, the reference output voltage corresponding to zero RF input depends on the ratio of the resistor divider and is independent of the resistor value. By using the configuration of the resistor 124, 130 and current mirror 216 operating as a resistor divider, the power detector 120 is independent of the temperature variations of the network 100 as well as its process variations.

RF to DC conversion for the power detector is realized by the common- source configured LDMOS FET transistor 122. The non-linear LDMOS I-V relationship of the transistor 122, which generally operate as a function of a square law, varies the DC drain current of transistor 122 according to the RF input power. This DC current is fed into the current mirror 126 or 216, which can be a PMOS current mirror as described above. The current mirror drives the resistive load 124 and the resistive load converts the current to the output voltage. The clamped LDMOS transistor 110 in series with resistor 130 provides the quiescent bias current that is also independent of temperature variations of the network 110 as well as process variations.

As already mentioned, the resistive load of resistor 124 and the resistor 130 indirectly form another resistor divider for the network 100. Therefore, the output voltage of the power detector is independent of temperature and process variations. By taking advantages of the properties of semiconductor process, integrating the whole circuits on the same chip and referring the coupling coefficient, the bias and the output to the ratio of the resistors instead of the absolute values, process and temperatures insensitive output of the power detector is achieved. With the fewest transistors, a power detector is realized so that the output voltage is linearly proportional to the RF power. High detection accuracy and wide-band response are achieved due to the topology of the present invention. Moreover, calibration and zeroing processes in the application are avoided. In addition, by using the dead area of the silicon die for the power detector as part of an integrated circuit, board area and external components such as couplers and detectors can be saved and costs can be reduced.

As seen, the use of the resistive voltage divider coupled to the RF signal establishes the power detector of the present invention. The coupled power is depended on the ratio of the resistance divider. Therefore, it is independent of variations within the integrated circuit as long as they are on the same layer and close to each other.

Therefore the present invention creates an integrated resistive coupler where the output is highly repeatable while being independent of variations. The detector of the present invention produces a wide band response and linear output versus RF power. Moreover, the output is modulation independent with a high transducer gain and no calibration is needed.

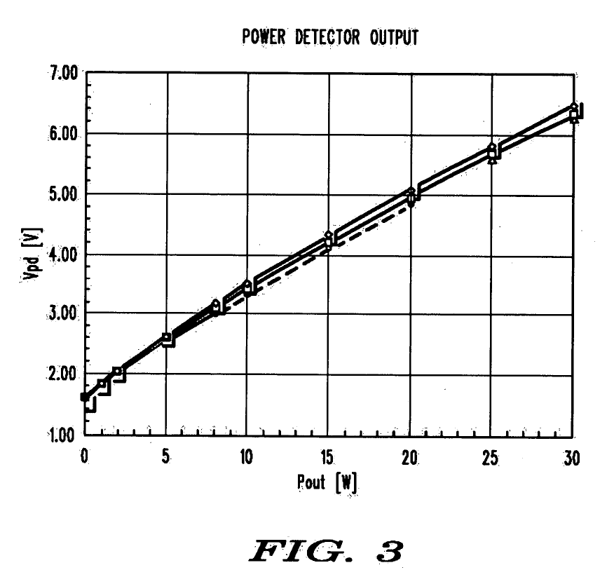

Referring now to FIG. 3, power detection measurements associated with a power detector of the present invention are shown. The x-axis represents the power to be detected in linear scale while the y-axis represents the output of a power detector of the present invention. Solid line represents the output with continuous wave (CW) input while dotted line represents output with IS-95 CDMA input. Also presented are results from three different samples. These results illustrate that present invention is a highly repeatable, accurate, low cost linear power detector.

In the foregoing specification, specific embodiments of the present invention have been described. However, one of ordinary skill in the art appreciates that various modifications and changes can be made without departing from the scope of the present invention as set forth in the claims below. Accordingly, the specification and figures are to be regarded in an illustrative rather than a restrictive sense, and all such modifications are intended to be included within the scope of present invention. The benefits, advantages, solutions to problems, and any element(s) that may cause any benefit, advantage, or solution to occur or become more pronounced are not to be construed as a critical, required, or essential features or elements of any or all the claims. The invention is defined solely by the appended claims including any amendments made during the pendency of this application and all equivalents of those claims as issued.

I claim:

1. An integrated LDMOS radio frequency circuit comprising:
a LDMSO power amplifier, and
a power detector circuit integrally coupled to the LDMOS power amplifier circuit.

2. The integrated LDMOS circuit according claim 1 wherein the power detector circuit comprises at least two LDMOS transistors.

3. The integrated LDMOS circuit according to claim 1 wherein the power detector circuit comprises a resistive voltage divider coupled to the power amplifier circuit.

4. The integrated LDMOS circuit according to claim 1 further comprising at least one PMOS transistor coupled to the power detector circuit.

5. The integrated LDMOS circuit according to claim 1 further comprising a circuit mirror coupled to the power detector circuit.

6. The integrated LDMOS circuit according to claim 5 wherein the circuit mirror includes at least one PMOS transistor.

7. The integrated LDMOS circuit according to claim 1 further comprising:
a clamped LDMOS transistor coupled to the power detection circuit, and
a first resistor coupled between the clamped LDMOS transistor and a second resistor, and wherein the second resistor is coupled to a current mirror coupled to the second resistor.

8. The integrated LDMOS circuit according to claim 1 wherein the power detector circuit is independent of process variation caused by the semiconductor process and manufacturing.

9. The integrated LDMOS circuit according to claim 1 wherein the power detector circuit is independent of temperature variation caused by the power amplification circuit.

10. The integrated LDMOS circuit according to claim 1 wherein the power detector circuit comprising:
a first resistor coupled to the LDMOS power amplifier, and
a second resistor coupled to the power detection circuit wherein the first and second resistors operate as a voltage divider for the LDMOS circuit.

11. The integrated LDMOS circuit according to claim 1 wherein the power detector circuit is configured so that the LDMOS circuit does not need to be tuned.

12. The integrated LDMOS circuit according to claim 1 wherein the power detector circuit is configured so that the LDMOS circuit does not need to be calibrated.

13. The integrated LDMOS circuit according to claim 1 further comprising a clamped bias circuit having a power source and a first LDMOS transistor, and the power detector circuit comprises a first resistor couple to the first LDMOS transistor and a second resistor coupled between the power source and the first LDMOS transistor.

14. The integrated LDMOS circuit according to claim 13 wherein the power detector circuit further comprises a second LDMOS transistor coupled to the clamped bias circuit.

15. The integrated LDMOS circuit according to claim 14 further comprising a current mirror coupled to the second LDMOS transistor and the first resistor.

16. The integrated LDMOS circuit according to claim 15 wherein the current mirror comprises at least one PMOS transistor.

17. An integrated power detection circuit, the circuit comprising:
a first LDMOS transistor;
a first resistor coupled between the first LDMOS transistor and a power source;
a second LDMOS transistor coupled to the first LDMOS transistor;
at least one PMOS transistor coupled between the second LDMOS transistor and a second resistor, wherein the PMOS transistor functions as a current mirror for the circuit and the second transistor functions as a resistive load for the circuit.

18. The power detection circuit according to claim 17 wherein the first and the second resistors and current mirror provide a power detection circuit independent of process variation of the amplifier circuit.

19. The power detection circuit according to claim 17 wherein the first and the second resistors and current mirror provide a power detection circuit independent of temperature variation of the amplifier circuit.

20. The power detection circuit according the claim 17 wherein the second LDMOS circuit and the first resistor self bias the power detection circuit.

21. The power detection circuit according to claim 17 wherein the first and second resistor form a resistive voltage divider.

22. The power detection circuit according to claim 17 wherein the resistor divider provides a circuit that does not need to be tuned.

23. The power detection circuit according to claim 17 wherein the resistor divider provides a circuit that does not need to be calibrated.

24. The power detection circuit according to claim 17 wherein the second LDMOS transistor converts radio frequency power to DC current.

25. A power detection circuit for an LDMOS radio frequency transmitter, the power detection circuit comprising:
a power source;
a first LDMOS transistor coupled to the power source, and
a resistor divider coupled to the first LDMOS transistor wherein the resistor divider operates as an amplification circuit for the power detector.

26. The power detection circuit according to claim 25 wherein the resistor divider comprises a first resistor.

27. The power detection circuit according to claim 26 wherein the resistor divider further comprises a second resistor coupled between the power source and the first LDMOS transistor.

29. The power detection circuit according to claim 25 further comprising at least one PMOS transistor coupled between the first LDMOS transistor and the resistor divider.

30. The power detection circuit according to claim 29 wherein the PMOS transistor operates as a circuit mirror for the power detection circuit.

31. The power detection circuit according to claim 25 further comprising a second LDMOS transistor coupled between the first LDMOS transistor and the resistor divider wherein the second LDMOS transistor converts the radio frequency power to DC current.

32. The power detection circuit according to claim 25 further comprising at least one PMOS transistor coupled between the first LDMOS transistor and the resistor divider wherein the PMOS transistor operates as a current copier for the circuit, a second LDMOS transistor fro converting radio frequency power into DC current and wherein the resistor divider comprises a first resistor coupled to the PMOS transistor and the second LDMOS transistor and a second resistor couple between the power source and the first LDMOS transistor.
